(19) United States
(12) Patent Application Publication
(10) Pub. No.: US 2007/0251458 A1
(43) Pub. Date: Nov. 1, 2007

(54) Cleanroom-Capable Coating System

(75) Inventors: Dietrich Mund, Obersüßbach (DE); Wolfgang Fukarek, Fischbach bei Amsdorf (DE); Jurgen Leib, Freising (DE)

Correspondence Address: DEMONT & BREYER, LLC, 100 COMMONS WAY, HOLMDEL, NJ, 07733, US

(73) Assignee: SCHOTT AG, 55122 Mainz (DE)

(21) Appl. No.: 11/572,254

(22) PCT Filed: Jul. 14, 2005
(86) PCT No.: PCT/EP05/07653

§ 371 Date: May 8, 2007

(30) Foreign Application Priority Data
Jul. 21, 2004 (DE) 10 2004 035 336.0

(51) Int. Cl. C23C 14/56

(52) U.S. Cl. 118/729

(57) ABSTRACT

The invention relates to a cleanroom-capable coating system for PVD or CVD processes having at least one vacuum coating chamber, in which vitreous, glass-ceramic and/or ceramic layers deposited. A first opening of the vacuum coating chamber is connected via a separately evacuable vacuum airlock chamber (load lock) to a cleanroom, the vacuum airlock chamber comprising transport means for delivering substrates into the vacuum coating chamber and for taking substrates out of the vacuum coating chamber, and a second opening of the vacuum coating chamber connects the vacuum coating chamber to a grayroom area separated from the cleanroom.

The invention relates to a vacuum coating system for vapor deposition processes, particularly for coatings of vitreous, glass-ceramic or ceramic materials, which is suitable for cleanroom technologies.

Vapor deposition processes (deposition of layers from the vapor phase) are essential components for the production of modern products in many branches of industry. Development for example in optics, optoelectronics or semiconductor technology is driven by ever smaller structures, higher functionality, higher productivity and high qualitative requirements.

Layers of inorganic, particularly vitreous, glass-ceramic or ceramic materials are employed for a wide variety of applications.

In order to implement modern technologies in optics, optoelectronics, MEMS applications and semiconductor technology, for example, methods have been developed for passivation, packaging and production of structured layers on substrates by means of vitreous coatings (SCHOTT patent applications DE 102 22 964 A1; DE 102 22 958 A1; DE 102 22 609 A1).

Fundamentally differing techniques may be envisaged for depositing vitreous, glass-ceramic or ceramic layers, for example CVD methods (chemical vapor deposition) or PVD methods (physical vapor deposition). The selection of a suitable method is dictated both by the coating material, the required coating rates, requirements of the coating quality, but above all by the thermal stability of the substrate.

Since the substrates to be coated, for example integrated circuits on silicon wafers, are often heat-sensitive, primarily coatings which allow coating below 120° C. are viable in this case. PVD methods, particularly electron beam evaporation, have been found to be suitable processes for coating heat-sensitive substrates with a glass or glass-ceramic layer, since the vitreous, glass-ceramic or ceramic layers can be evaporated and deposited with high coating rates and high purity as vitreous multi-component layers.

Corresponding coating methods and systems are known inter alia from the documents cited above.

A restriction found for using the coating technology is the buildups of vitreous, glass-ceramic or ceramic layer material in the vacuum chamber and on system components contained in it, which become released in the form of minute particles during and after the coating process when cooling the system and when opening the vacuum chamber, and lead to contaminations of the environment. When opening the chamber, the buildup of water molecules from the ambient air further accelerates the delamination process considerably.

Since the fabrication of high-precision, microstructured and microelectronic components must generally take place under cleanroom conditions, coating with vitreous, glass-ceramic or ceramic layers by conventional coating systems cannot be carried out in cleanrooms.

Furthermore, such coating processes necessitate elaborate procedures of cleaning the chamber and environment after each time the vacuum chamber is opened. During this time, the system is not available for fabrication. In many applications the chamber is opened after each coating process, and at least when it is necessary to clean the chamber inner walls and/or the system parts. This makes fabrication very elaborate and cost-intensive.

It is therefore an object of the invention to provide a cleanroom-capable coating system, particularly for coatings with vitreous, glass-ceramic or ceramic materials. It is a further object of the invention to increase efficiency in the ultraclean fabrication of highly sensitive components.

The object is achieved in a surprisingly simple way by a coating system having at least one vacuum coating chamber in which vitreous, glass-ceramic and/or ceramic layers are deposited from the vapor phase onto substrates, wherein the vacuum coating chamber comprises a first opening, the first opening is connected via a separately evacuable vacuum airlock chamber to a cleanroom, the vacuum airlock chamber comprising transport means for delivering substrates into the vacuum coating chamber and for taking substrates out of the vacuum coating chamber, and the vacuum coating chamber comprises a second opening which connects the vacuum coating chamber to a grayroom area separated from the cleanroom.

The separately evacuable vacuum airlock chamber (load lock) makes it possible to change the substrates without venting and re-evacuating the vacuum coating chamber. As is known, such load lock techniques are used to improve the efficiency of the system since the vacuum coating chamber does not need to be vented and re-evacuated each time the substrates are changed, and long downtimes of the system are avoided.

Only using the system according to the invention, however, in which the vacuum coating chamber comprises an additional opening to a grayroom and the load lock technique is used, can the delivery and removal of the substrates take place directly from/to a cleanroom, since the system can be operated in such a way that the vacuum coating chamber is no longer at any time in direct connection with the cleanroom, and contamination is thereby avoided.

Via the second opening which connects the vacuum coating chamber to a grayroom area separated from the cleanroom, the vented vacuum coating chamber can then be opened for maintenance, and if necessary to change the target, with the vacuum airlock chamber closed.

It is thus possible for a multiplicity of coating processes to take place successively, without having to re-evacuate the coating chamber.

By means of the load lock technique a plurality of substrates, which are contained for example in a cassette system, can advantageously be transported by a suitable handler from the cleanroom into the vacuum airlock chamber and, after evacuating it, from there into the vacuum coating chamber and vice versa.

The coating system according to the invention is not constrained to any particular coating process; it is suitable both for PVD processes (physical vapor deposition) and for CVD processes (chemical vapor deposition).

For coating heat-sensitive substrates with vitreous layers, as takes place for example in semiconductor fabrication, it is preferable to employ electron beam evaporation, thermal evaporation or pulsed plasma ion beam evaporation.

When applying relatively thick and/or very porous and/or flaking-prone layer materials, and/or in order to reduce the contamination of the substrates and the cleanroom even further, the vacuum coating chamber may preferably comprise a shielding device or cladding which protects the vacuum chamber inner walls and/or the system parts arranged in the chamber against undesired buildups of the layer starting material as well as detachment of particles or flaking.

Typical layer thicknesses for hermetic encapsulation or the microstructuring of semiconductor components, optical microcomponents, MEMS, optoelectronic components etc. with vitreous, glass-ceramic or ceramic layers lie in ranges between 0.01 μm and 100 μm. Correspondingly “thick” and brittle vitreous buildup layers therefore occur on the shielding device.

Delamination, both when opening the vacuum chamber and during the coating process itself, is prevented if the shielding device consists of a material which has approximately the same expansion coefficient as the layer material. This avoids stresses between the shielding device and the build-up layer during temperature changes, and therefore contamination by released layer particles. Owing to the very small structure sizes of the components to be fabricated, such contaminations would render them unusable.

The shielding device preferably consists of a vitreous, glass-ceramic or ceramic material, particularly of the same material as the layer to be applied, since then both the shielding device and the layer have approximately the same expansion coefficient, and preferably the same expansion coefficient.

In order to protect both the chamber inner walls and the components arranged in the chamber, such as substrate holders, shutters etc., it is advantageous to configure the shielding device in multiple parts. For example, the chamber inner walls may be protected by barriers made of glass elements, the substrate holder by a glass covering with corresponding recesses for the substrate, and other components by adapted glass coverings.

Since the shielding device prevents contamination of the vacuum coating chamber, the number of coating processes possible without opening the vacuum coating chamber can be increased further, for example when the substrates are likewise changed under vacuum conditions. It is clear that the efficiency of the system is thereby further increased considerably.

In another suitable embodiment of the coating system, the substrate holder is configured for receiving a plurality of substrates, in particular for receiving a plurality of wafers to be coated. The efficiency of the system can likewise be increased by this.

It is within the scope of the invention to configure the coating system preferably with a plurality of vacuum coating chambers. These are respectively connected by a first opening each via a separately evacuable vacuum airlock chamber to the cleanroom, and respectively via a separate second opening to the grayroom area separated from the cleanroom. Substrates can thereby be transported from one vacuum coating chamber to another inside a cleanroom, and a flexible system concept can be implemented.

The coating system according to the invention is suitable particularly for the efficient coating of wafers to produce optical, microelectronic and optoelectronic components under cleanroom requirements. The coating to fabricate these components comprises for example encapsulation, chip-size packaging, wafer-level packaging etc. with vitreous, glass-ceramic and/or ceramic layers which, for example, function as passivation layers and diffusion barriers.

The cleanroom-capable coating system according to the invention is not, however, restricted to these applications.

The invention will be explained in more detail below with reference to an exemplary embodiment, for which

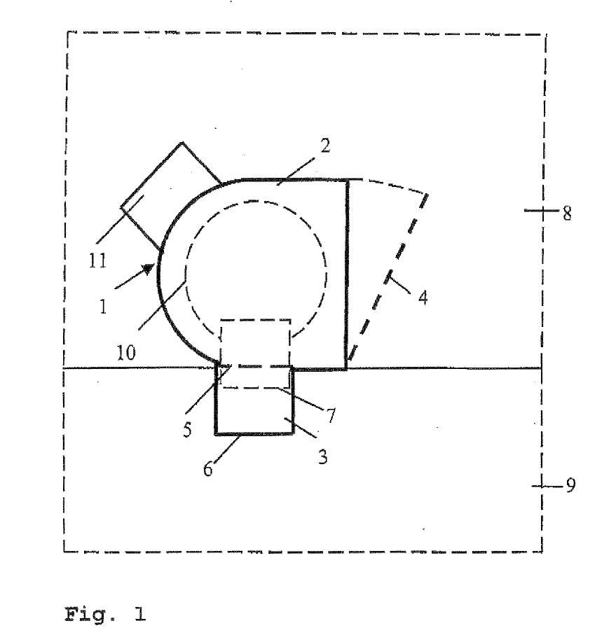

FIG. 1 shows the schematic representation of a coating system

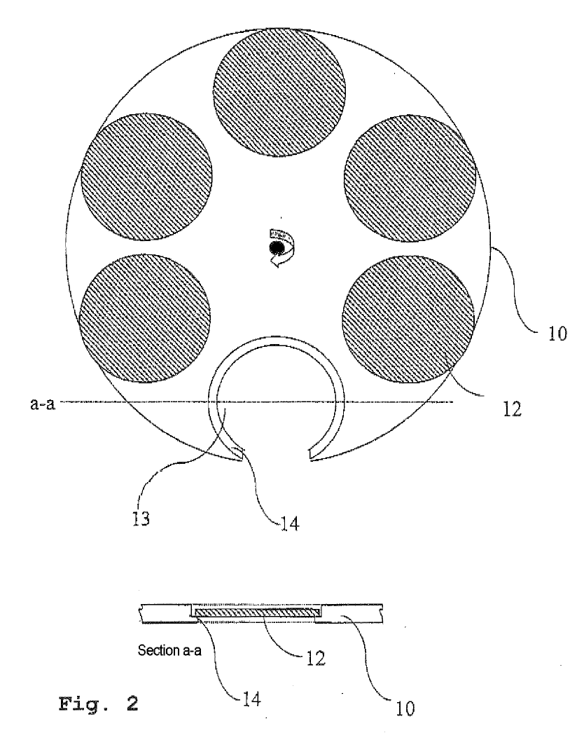

FIG. 2 shows the schematic representation of a substrate holder for wafers

The invention will be explained with reference to an electron beam coating system in which a plurality of substrates, for example silicon wafers, are coated with a microstructured glass layer. Further details of the production and structuring of such glass layers are disclosed for example in DE 102 22 964 A1, DE 102 22 958 A1 and DE 102 22 609 A1.

The layer starting material in the form of a glass target made of SCHOTT glass No. 8329 or SCHOTT glass No. G018-189 is evaporated in the vacuum coating chamber (2) of the cleanroom-capable coating system (1) represented in FIG. 1 by an electron beam, the glass vapor being deposited on the substrate and the condensed layer on the substrate surface also being densified by plasma ion bombardment (PIAD).

Vitreous layers with layer thicknesses of from 0.1 to 100 μm are thereby deposited on the substrate surface.

The coating system (1) represented in FIG. 1 consists of a vacuum coating chamber (2), a vacuum airlock chamber (3) and the vacuum pumps (12). The first opening (5) of the vacuum coating chamber (2) connects the vacuum coating chamber (2) to the vacuum airlock chamber (3), a vacuum valve being arranged in the first opening (5) for independent, separate evacuation of the two chambers (2, 3). There is a handler (7) for transporting and changing the substrates in the vacuum airlock chamber (3). The substrate holder (10) is represented in more detail in FIG. 2, and is configured for 6 wafers (12). The vacuum airlock chamber (3) can be opened in the direction of the cleanroom via a further vacuum valve (6). The second opening (4) of the vacuum coating system (2) is a chamber door opening into the grayroom (8). The cleanroom (9) and the grayroom (8) are separated room areas.

Process for changing substrates with the vacuum coating chamber (2) evacuated:

From the cleanroom (9) with the vacuum valve of the first opening (5) and the vacuum valve (6) open, the wafers (12) are put into the handler (7) from the cleanroom (9). The vacuum valve (6) is closed and the vacuum airlock chamber (3) is opened. After opening the vacuum valve of the first opening (5), the handler (7) can bring the wafers (12) into the vacuum coating chamber (2) and arrange them on the substrate holder (10). The substrate holder (10) represented in more detail in FIG. 2 comprises circular recesseses (13) for holding the wafers (12) with an annular bearing surface (14), onto which the wafers (12) are placed. Once all the wafers (12) have been arranged on the substrate holder (10), the handler (7) moves back into the vacuum airlock chamber (3) and corresponding coating of the wafers (12) is carried out as described above. The handler (7) subsequently takes the wafers (12) from the substrate holder (10) and transports them back into the vacuum airlock chamber (3). The vacuum valve of the first opening (5) is closed and the vacuum airlock chamber (3) is aerated. After opening the vacuum valve (6), the wafers (12) whose coating has been finished can be taken out and the handler (7) can be refilled. The vacuum coating chamber (2) remains evacuated and at the operating temperature while changing the substrates.

This process may be repeated until the target material is used up and/or the vacuum coating chamber (2) and system parts contained in it require maintenance. The number of chips which may for example be coated at least until a target is used up, and therefore without aerating and re-evacuating the vacuum coating chamber (2), depends on the number and size of the wafers (12) which are coated in a coating process, the chip size and the layer thickness. In the coating system (1), for example, 8 wafers with a diameter of 100 mm could also be arranged on the substrate holder (10). With chip sizes of 2 mm*2 mm and a layer thickness of 10 μm, approximately 5000 chips could then be coated with one target. For wafer chips with a larger diameter, for example 200 mm, 4 wafers could be arranged on the substrate holder (10) in the same coating system (1). With an equal chip size and a layer thickness of 1 μm, approximately 400,000 chips could then be coated per target.

Maintenance of the coating system and/or changing the target: The vacuum coating chamber (2) must be cleaned at regular intervals and/or a new target must be provided. This is done with the vacuum airlock chamber (3) closed from the grayroom (8), so as to prevent any contact with the substrates and the cleanroom (9). To this end, the vacuum coating chamber (2) is aerated. By opening the chamber door, cleaning and/or a target change can be carried out via the second opening (4) from the grayroom (8). The vacuum coating chamber (2) is subsequently re-closed and evacuated, and further coating of substrates can be carried out.

It is, however, not absolutely necessary to change the target via the opening (4). In addition to changing the substrate, a target may also be changed while maintaining the vacuum. In this case the efficiency of the system can be increased even further, since the vacuum coating chamber (2) then only needs to be opened for maintenance purposes. This is possible in particular when the vacuum coating chamber (2) additionally comprises a shielding device. The maintenance intervals for the vacuum coating chamber (2) can thereby be increased even further, and the efficiency considerably increased.

1. A coating system (1) having at least one vacuum coating chamber (2) in which at least one of vitreous, glass-ceramic and ceramic layers are deposited from the vapor phase onto substrates, characterized in that the vacuum coating chamber (2) comprises a first opening (5), the first opening (5) is connected via a separately evacuable vacuum airlock chamber (3) to a cleanroom (9), the vacuum airlock chamber (3) comprising transport means (7) for delivering substrates into the vacuum coating chamber (2) and for taking substrates out of the vacuum coating chamber (2), and the vacuum coating chamber (2) comprises a second opening (4) which connects the vacuum coating chamber (2) to a grayroom area (8) separated from the cleanroom (9).

2. The coating system (1) as claimed in claim 1, characterized in that it comprises a CVD system.

3. The coating system (1) as claimed in claim 1, characterized in that it comprises a PVD system.

4. The coating system (1) as claimed in claim 3, characterized in that it comprises means for one of: electron beam evaporation, thermal evaporation and pulsed plasma ion beam evaporation.

5. The coating system (1) as claimed in claim 4, characterized in that it comprises means for plasma ion-assisted vapor deposition of the layer.

6. The coating system (1) as claimed in claim 1, characterized in that the coating chamber (2) comprises a shielding device to protect, against undesired layer buildup, at least one of: an inner wall of the coating chamber (2) and a system part lying in the coating chamber.

7. The coating system (1) as claimed in claim 6, characterized in that the shielding device comprises the same expansion coefficient as the layer to be applied onto the substrate.

8. The coating system (1) as claimed in claim 7, characterized in that the shielding device comprises at least one of: a vitreous material, a glass-ceramic material, and a ceramic material.

9. The coating system (1) as claimed in claim 8, characterized in that the material of the shielding device corresponds to the material of the layer being applied.

10. The coating system (1) as claimed in claim 6, characterized in that the shielding device is in multiple parts.

11. The coating system (1) as claimed in claim 1, characterized in that the transport means for delivering substrates into the vacuum coating chamber (2) and for taking substrates out of the vacuum coating chamber (2) comprise a handler (7) for simultaneously transporting a plurality of substrates.

12. The coating system (1) as claimed in claim 11, characterized in that the first opening (5) of the vacuum coating chamber (2) comprises a vacuum valve for separating the vacuum coating chamber (2) from the vacuum airlock chamber (3).

13. The coating system (1) as claimed in claim 1, characterized in that the vacuum coating chamber (2) comprises a substrate holder (10) for a plurality of substrates to be coated.

14. The coating system (1) as claimed in claim 13, characterized in that the vacuum coating chamber (2) comprises a substrate holder (10) for a plurality of wafers (12) to be coated.

15. The coating system (1) as claimed in claim 1, characterized in that a plurality of vacuum coating chambers (2) respectively comprise a first opening (5), each of the first openings (5) respectively being connected via a separately evacuable vacuum airlock chamber (3) to a cleanroom (9), and respectively comprise a second opening (4) which connects the vacuum coating chambers (2) to a grayroom area (8) separated from the cleanroom (9).
